(19) United States
(12) Patent Application Publication
(10) Pub. No.: US 2026/0150477 A1
(43) Pub. Date: May 28, 2026

(54) HELICAL GRAPHENE NANORIBBON FOR ORGANIC ELECTROCHEMICAL TRANSISTORS AND CONFORMABLE ELECTRODE ARRAY

(71) Applicants: THE TRUSTEES OF COLUMBIA UNIVERSITY IN THE CITY OF NEW YORK, New York, NY (US); CORNELL UNIVERSITY, Ithaca, NY (US)

(72) Inventors: Colin P. Nuckolls, New York, NY (US); Dion Khodagholy, New York, NY (US); Qifeng Jiang, New York, NY (US); Shayan Louie, New York, NY (US); Duncan Wisniewski, New York, NY (US); Fay W. Ng, New York, NY (US); Yu Zhong, Ithaca, NY (US)

(73) Assignees: THE TRUSTEES OF COLUMBIA UNIVERSITY IN THE CITY OF NEW YORK, New York, NY (US); CORNELL UNIVERSITY, Ithaca, NY (US)

(21) Appl. No.: 19/392,947

(22) Filed: Nov. 18, 2025

Related U.S. Application Data
(60) Provisional application No. 63/725,812, filed on Nov. 27, 2024.

(51) Int. Cl. H10K 10/46; H10K 10/84

(52) U.S. Cl. CPC H10K 10/491; H10K 10/481; H10K 10/84

(57) ABSTRACT

The disclosed subject matter provides methods of synthesizing a helical graphene nanoribbon (hGNR), and electrode arrays and transistors based thereon. The method includes polymerizing a perylene tetraester precursor with an alkyne monomer to form a polymer backbone; inducing the polymer backbone to visible-light-mediated photocyclization to generate a helical nanoribbon precursor; and post-functionalizing the helical nanoribbon precursor with imide groups having oligoethylene glycol substituents, thereby forming a substantially defect-free helical graphene nanoribbon adapted for mixed ionic and electronic conduction.

### CROSS-REFERENCE TO THE RELATED APPLICATION

This application claims priority to U.S. Provisional Patent Application Ser. No. 63/725,812, filed Nov. 27, 2024, which is hereby incorporated by reference in its entirety.

### GRANT INFORMATION

This invention was made with Government Support under Grant No. CHE-2204008 awarded by the National Science Foundation. The Government has certain rights in the invention.

### BACKGROUND

Graphene nanoribbons (GNRs) are one-dimensional carbon-based nanomaterials with certain optoelectronic, mechanical, and chemical properties that make them attractive for electronic and quantum technologies. Certain GNR synthesis techniques do not provide defect-free, functionalized GNRs that can be produced at scale and integrated into mixed ionic/electronic devices.

There exists a need for developing stable, n-type organic mixed ionic/electronic conductors (OMIECs). Such OMIECs can provide high-performance organic electrochemical transistors, complementary logic circuits, and bioelectronic interfaces.

### SUMMARY

The disclosed subject matter provides techniques for synthesizing helical graphene nanoribbons (hGNRs) and their use in electronic applications, including conformable electrode arrays and organic electrochemical transistors. Applications of the disclosed subject matter can achieve long-term, stable, and high-performance recordings for in vivo neuron activities.

In one aspect, the disclosed subject matter provides a method of synthesizing a helical graphene nanoribbon (hGNR). An example method can include polymerizing a perylene tetraester with an alkyne monomer to form a polymer backbone, inducing the polymer backbone to undergo visible-light-mediated photocyclization to generate a helical nanoribbon precursor, and post-functionalizing the helical nanoribbon precursor with imide groups having oligoethylene glycol substituents along cove edges of the nanoribbon, thereby forming a substantially defect-free hGNR.

In certain embodiments, the polymerizing is performed by a Stille coupling reaction under room-temperature conditions. The Stille coupling reaction can be catalyzed by a palladium-based catalyst and conducted in an organic solvent selected from toluene, dimethylformamide (DMF), and N-methylpyrrolidone (NMP). The polymerization can also be configured to suppress homo-coupling side reactions.

In certain embodiments, the visible-light-mediated photocyclization is performed in a flow reactor. The method can further comprise depositing the defect-free hGNR as a thin film on a substrate to form a channel layer of an organic electrochemical transistor.

In certain embodiments, at least a portion of the imide groups having oligoethylene glycol substituents are functionalized with crown ether groups. The crown ether groups are selected at least one of 12-crown-4, 15-crown-5, and 18-crown-6. Alternatively, at least a portion of the imide groups having oligoethylene glycol substituents is functionalized with methoxy polyethylene glycol.

In another aspect, the disclosed subject matter provides a conformable electrode array for recording electrical signals form neural tissue of a subject. An example array can include a substrate, a plurality of electrodes patterned on the substrate, and a conductive coating disposed on at least one of the electrodes. In certain embodiments, the conductive coating comprises a helical graphene nanoribbon (hGNR) having oligoethylene glycol-functionalized imide groups along cove edges of the nanoribbon.

In certain embodiments, the conformable electrode array is configured to interface with the neural tissue and to record the electrical signals therefrom. In certain embodiments, the electrodes have dimensions of about 40 micrometers by about 40 micrometers with an interelectrode spacing of about 500 micrometers. The array can be configured to record neuronal oscillations, including delta spindles, during sleep states of the subject.

In another aspect, the disclosed subject matter provides an organic electrochemical transistor (OECT). An example transistor can include a channel layer comprising a helical graphene nanoribbon (hGNR) having a defect-free extended graphitic backbone and a plurality of oligoethylene glycol-functionalized imide groups along cove edges of the hGNR, a substrate having the channel layer patterned thereon, a source electrode and a drain electrode in electrical communication with the channel layer, and a gate electrode configured to modulate ionic and electronic transport within the channel layer through an electrolyte.

In certain embodiments, the source electrode and the drain electrode comprise a titanium/gold bilayer, and the gate electrode comprises a silver/silver chloride (Ag/AgCl) electrode. The electrolyte can comprise an aqueous solution selected from phosphate-buffered saline (PBS) and saline. In certain embodiments, the transistor can further include an insulating layer disposed on the source and drain electrodes and can be configured to integrate with a p-type organic conductor to fabricate a complementary inverter.

### BRIEF DESCRIPTION OF THE DRAWINGS

Embodiments of the disclosed subject matter are described in detail by reference to these figures referenced below.

FIGS. 1A-1C illustrate a schematic structure and physical property of helical graphene nanoribbon (hGNR) according to certain embodiments of the disclosed subject matter. FIG. 1A is a schematic diagram of a cove-edge graphene nanoribbon including the graphitic core and cove-edge substituents. FIG. 1B is a schematic diagram of an exemplary hGNR functionalized along the cove edge with imide groups having oligoethylene glycol side chains. FIG. 1C depicts a plot comparing normalized transconductance and μC* (mobility×volumetric capacitance) of an organic electrochemical transistor (OECT) incorporating the hGNR versus certain devices based on n-type organic polymer materials.

FIG. 2 provides a schematic depiction of electrochemical doping and de-doping processes in hGNR thin films via ion ingress/egress and/or concomitant electronic doping.

FIG. 3A illustrates a synthetic process of preparing hGNR according to certain embodiments of the disclosed subject matter. FIG. 3B illustrates a microstructural protocol for preparing hGNR, showing the structural modifications during different stages. FIG. 3C illustrates reaction conditions showing the reaction difference between the room-temperature Stille polycondensation for yielding helical perylene tetraester (hPTR, defect-free precursor) and a thermally activated Stille yielding defective hPTR (D-hPTR, defect-containing precursor). FIG. 3D illustrate a comparison of the aromatic region of ¹H NMR for hPTR and D-hPTR. FIG. 3E provides a normalized UV-Vis absorption spectra of hGNR and D-hGNR, demonstrating a sharper peak for defect-free hGNR. FIG. 3F provides a comparison chart of OECT transconductance and temporal response (τₒₙ/τ_{off}) between hGNR and D-hGNR. FIG. 3G provides a comparison chart of volumetric capacitance and electronic mobility for hGNR and D-hGNR.

FIG. 4A illustrates a hGNR-based probe incorporating a conformable electrode array for in vivo electrophysiological applications according to certain embodiments of the disclosed subject matter. FIG. 4B illustrates a delta-spindle local field potential (LFP) trace recorded on Day 9 of chronic recording. FIG. 4C illustrates time-frequency spectrogram of an LFP recording showing sleep-state classification. FIG. 4D illustrates benchtop electrode impedance measurements for polymer-coated electrodes showing the electrode geometry. FIG. 4E shows time-frequency spectrograms across multiple days showing reproducible spindle activity. FIG. 4F shows in vivo electrode impedance results from remaining functional channels over the recording period.

FIGS. 5A-5G illustrate electrical characterization of the OECT device incorporating the hGNR. FIG. 5A illustrates a schematic of a representative OECT according to certain embodiments of the disclosed subject matter. FIG. 5B shows a spectroelectrochemical absorption spectra of hGNR during reduction from +0.1 V to −0.7 V vs. Ag/AgCl (gate electrode) for the bias voltage relative to the gate electrode. FIG. 5C illustrates representative transfer characteristics and transconductance curve for an hGNR-based OECT, with an inserted diagram depicting top-view microscopy photograph of the channel region of the hGNR-based OECT. Scale bar: 50 μm. FIG. 5D illustrates representative output characteristics of the hGNR-based OECT. FIG. 5E illustrates a representative temporal response of the drain current of the hGNR-based OECT in response to a 0.7 V square wave V_{G} pulse. FIG. 5F illustrates voltage transfer characteristics and gain of a complementary inverter based on the hGNR and a conjugated polymer based on thieno[3,2-b]thiophene with glycol side chains (p(g2T-TT)). FIG. 5G illustrates a switching stability of the hNGR/p(g2T-TT) inverter with a switching frequency of 8 Hz.

FIGS. 6A-6D illustrate exemplary synthetic protocols and structural characterizations associated with the preparation of hGNRs and D-hGNR functionalized with methoxy polyethylene glycol mPEG4 according to certain embodiments of the disclosed subject matter.

FIGS. 7A-7C illustrate structural variants of contorted acene nanoribbons via variants reaction conditions according to certain embodiments of the disclosed subject matter.

FIGS. 8A-8D illustrate the electrochemical performance and spectroelectrochemical behavior of crown-ether-functionalized hGNRs and with methoxy polyethylene glycol functionalized hGNRs in organic electrochemical transistors (OECTs).

FIGS. 9A-9C illustrate a dual-transistor sensor configuration integrating hGNR-mPEG4 and hGNR-15c5 devices and the sensor's output current characteristics and real-time current response data.

It is to be understood that both the foregoing general description and the following detailed description are exemplary and are intended to provide further explanation of the disclosed subject matter.

### DETAILED DESCRIPTION

The disclosed subject matter provides materials and devices for bioelectronics. The disclosed subject matter provides techniques for designing and fabricating organic electrochemical transistors and conformable electrode arrays that employ helical graphene nanoribbons (hGNRs) as active channels and coating materials. The hGNRs described herein possess a defect-free extended graphitic backbone and functional imide groups bearing oligoethylene glycol side chains, which simultaneously enable stable mixed ionic and electronic conduction. By incorporating the hGNRs into transistor architectures and flexible electrode arrays, the disclosed subject matter achieves high signal fidelity, stable long-term performance in vivo, and compatibility with neural tissue.

As used herein, the term “graphene nanoribbon (GNR)” refers to a one-dimensional, elongated, ribbon-like nanostructure composed of sp²-bonded carbon atoms arranged in a fused polyaromatic π-conjugated backbone. GNRs can have armchair, zigzag, cove, or mixed edge topologies. The term “helical graphene nanoribbon (hGNR)” refers to a graphene nanoribbon having a cove-edge architecture that introduces a twist or contortion into the conjugated backbone, thereby imparting a helical or non-planar conformation. Unless noted otherwise, the hGNR in the disclosed subject matter typically refers to an extended, defect-free fused π-backbone functionalized at its cove edges with imide groups. The term “defect-free” refers to a structural quality of the helical graphene nanoribbon (hGNR) in which the π-conjugated backbone is substantially uninterrupted by irregularities such as homo-coupled diacetylene subunits, incomplete cyclization sites, or breaks in aromatic fusion. In certain embodiments, a substantial defect-free nanoribbon exhibits continuous aromatic conjugation along its helical backbone, resulting in sharp and well-defined absorption peaks in the ultraviolet-visible spectrum, a single broad resonance in the ¹H NMR spectrum consistent with uniform perylene proton environments, without additional or unexpected peaks indicative of side products, homo-coupling byproducts, or other structural defects. The term “D-hGNR” refers to a defective hGNR. In certain embodiments, the hGNR can comprise structures similar to graphene, such as contorted acene ribbons hGNR-mPEG4 or D-hGNR-mPEG4. The hGNR-12c4, hGNR-15c5, and hGNR-18c6 refer to a helical graphene nanoribbon functionalized at its cove edges with imide groups bearing 12-crown-4 ether moieties, 15-crown-5 ether moieties, and 18-crown-6 ether moieties, respectively.

As used herein, the term “cove edge” refers to the periodic concave indentation along the periphery of a graphene nanoribbon where functional groups, such as imides, can be attached.

As used herein, the term “imide functional group” refers to a nitrogen-containing functional group derived from a dicarboxylic acid, e.g., comprising the moiety —CO—NH—CO—. In certain embodiments, imides are substituted with oligoethylene glycol side chains to form polar substituents along the ribbon edge.

As used herein, the term “oligoethylene glycol (OEG)” refers to a linear or branched chain of ethylene oxide repeat units, typically having 2-20 units, optionally terminated with hydrogen, alkyl, or other substituents. In certain embodiments, OEG groups are covalently bonded to imide nitrogens.

As used herein, the term “organic electrochemical transistor (OECT)” refers to a transistor device in which the channel comprises an organic mixed ionic/electronic conductor whose conductance is modulated by ionic flow from an electrolyte under gating.

As used herein, the term “transconductance (Gₘ)” refers to the change in drain current per unit change in gate voltage of a transistor. “Normalized transconductance” refers to GM normalized to channel geometry (width/thickness) and reported in S·cm⁻¹. The term “figure of merit (μC*)” refers to a physical merit of an electronic device, e.g., the OECT, as an indicator of electronic performance thereof. A higher value of the figure of merit indicates improved performance for the OECT.

As used herein, the term “defect-free” refers to an hGNR featured with the conjugated backbone comprising substantially uninterrupted π-conjugation without significant structural breaks, homocoupling defects, or other disruptions detectable by NMR, UV-Vis, or crystallographic analysis.

As used herein, the term “conformable electrode array” refers to an array of microelectrodes fabricated on a flexible substrate (e.g., polymer film) such that the array can conform to the contour of biological tissue in the disclosed subject matter.

As used herein, the term “complementary inverter” refers to a logic circuit element comprising a p-type device and an n-type device electrically connected in a complementary configuration, wherein input voltage inversion is achieved.

As used herein, the terms “τₒₙ” and “τ_{off}” refer to the time constants characterizing the channel's turn-on and turn-off responses in OECTs following a gate voltage procedure, typically measured in microseconds or milliseconds.

As used herein, the term “Stille coupling” refers to a catalyzed cross-coupling reaction of organostannanes and aryl halides performed at or near ambient temperature, which suppresses side reactions and yields a more structurally precise precursor polymer. In certain embodiments, the Stille coupling can be occurred at room-temperature or thermal temperature. As used herein, the term “homo-coupling” refers to a side reaction during cross-coupling polymerizations in which two identical reactive monomers couple together, rather than forming the intended alternating copolymer linkage. In the context of synthesizing hGNRs, homo-coupling side reactions can generate diacetylene or other unintended subunits within the polymer backbone, leading to structural defects after cyclization. Suppression of homo-coupling is therefore essential to obtain a defect-free, fully conjugated nanoribbon framework.

As used herein, the term “photocyclization” refers to a photochemically induced ring-closure reaction, here used to convert an alkyne-bridged polymer precursor into a fused aromatic helical nanoribbon under visible-light irradiation. The term “cyclization” refers to the chemical transformation of a polymer backbone into a fused-ring structure through intramolecular bond formation. In certain embodiments, cyclization comprises visible-light-mediated photocyclization of a poly(PTE-alkyne) precursor to generate a helical nanoribbon precursor with extended π-conjugation along the backbone. As used herein, the term “post-functionalization” or “functionalization” refers to the chemical modification of a nanoribbon precursor after formation of the fused-ring backbone to introduce pendant functional groups. In certain embodiments, post-functionalization of a helical nanoribbon precursor (hPTR) introduces imide groups bearing oligoethylene glycol substituents along the cove edges of the nanoribbon, thereby yielding an hGNR with enhanced solubility, ionic transport, and interfacial compatibility.

As used herein, the term “in vivo stable” means that a material or device retains functional performance (e.g., impedance, recording capability) during continuous operation inside a living organism over at least one week, preferably at least two weeks, without significant degradation.

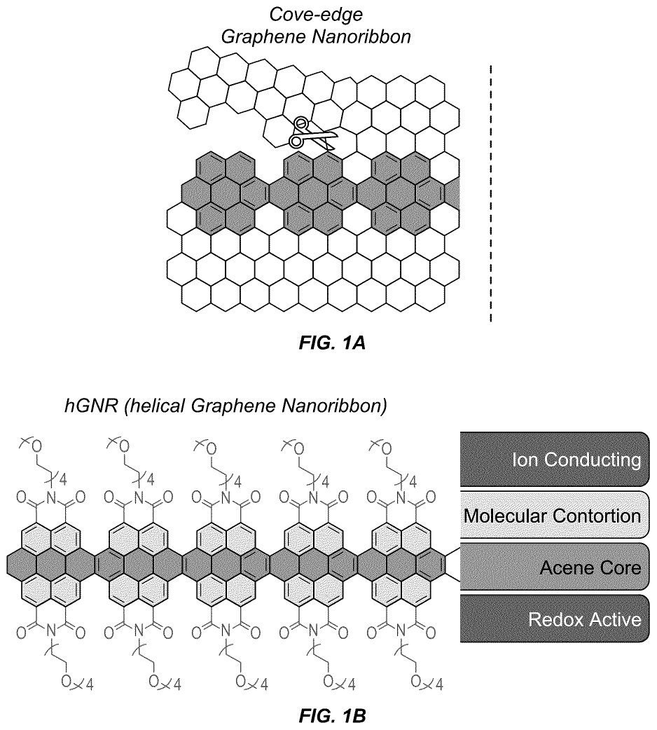

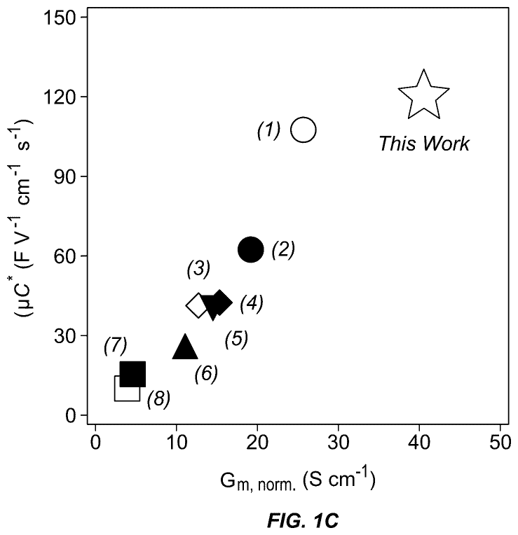

In certain embodiments, referring now to FIGS. 1A-1C, the disclosed subject matter provides an example cove-edge hGNR. The hGNR can include a graphitic core and cove-edge substituents, as shown in FIG. 1A. The cove edge structure provides concave sites along the ribbon backbone that can accommodate functional groups.

FIG. 1B depicts an exemplary hGNR having a defect-free extended conjugated backbone and functional groups positioned along the cove edges. In such an embodiment, the functional groups can include imide moieties having oligoethylene glycol side chains. The combination of an extended π-conjugation with polar functional edge substituents enables the hGNR to conduct both electronic carriers and ionic species, thereby facilitating the hGNR's suitable utilization as an active channel in the OECTs.

In addition, the functional cove edges can facilitate improved ion transport through the polar side groups and molecular contortions throughout the backbones. Furthermore, the imide groups positioned along the nanoribbon edges can lower the energy level of the conduction band, thereby enabling efficient electrochemical doping even under ambient conditions. Collectively, the hGNR in the disclosed subject matter can achieve improved or optimal electronic mobility, ion diffusion, and doping efficiency and can be applied as prospective materials in n-type organic mixed ionic/electronic conductor (OMIEC) applications.

FIG. 1C shows a representative plot comparing normalized transconductance and μC* (mobility×volumetric capacitance) of electronic devices such as OECTs, incorporating hGNRs relative to conventional devices based on n-type organic semiconducting polymers, demonstrating that the hGNR-based devices exhibit improved electronical properties. As demonstrated in FIG. 1C, the OECTs based on hGNRs exhibit recorded high levels of high transconductance (G_{m, norm.}=40.6 S·cm⁻¹) and μC* (120 FV⁻¹cm⁻¹s⁻¹) compared to the conventional n-type devices.

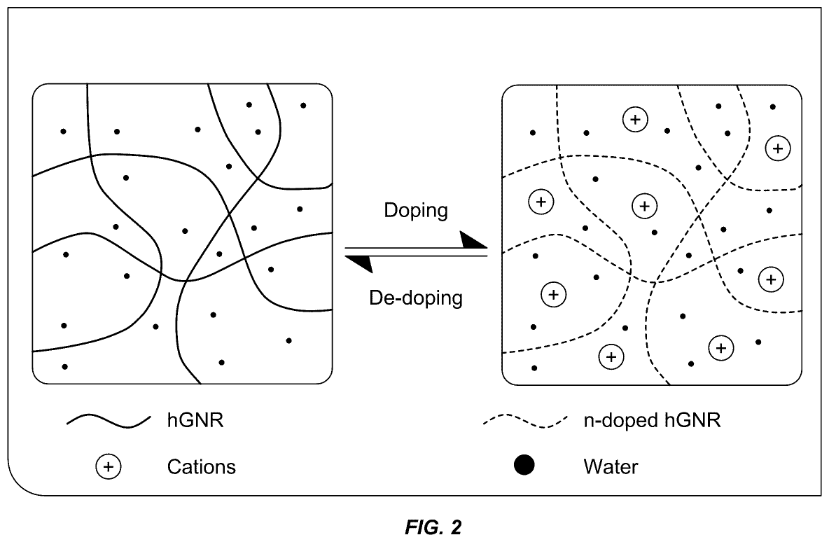

FIG. 2 illustrates an electrochemical mechanism of operation in hGNR-based thin films according to certain embodiments. As shown schematically, electrochemical doping and de-doping occur through ingress and egress of ions from the electrolyte into the hGNR channel material. This process can be accompanied by concomitant electron injection or withdrawal along the conjugated backbone, thereby modulating the mixed ionic/electronic conduction of the material. In certain embodiments, the electron injection or withdrawal can be implemented through application of a gate voltage in OECTs or via redox processes induced by an electrolyte, where electron injection corresponds to n-doping of the nanoribbon channel, while electron withdrawal corresponds to p-doping. Through the above mechanism, the polar oligoethylene glycol substituents can be coupled into the hGNR to facilitate ion transport through the ribbon structure, where the defect-free conjugated backbone provides efficient electron transport, resulting in improved performance of the OECT.

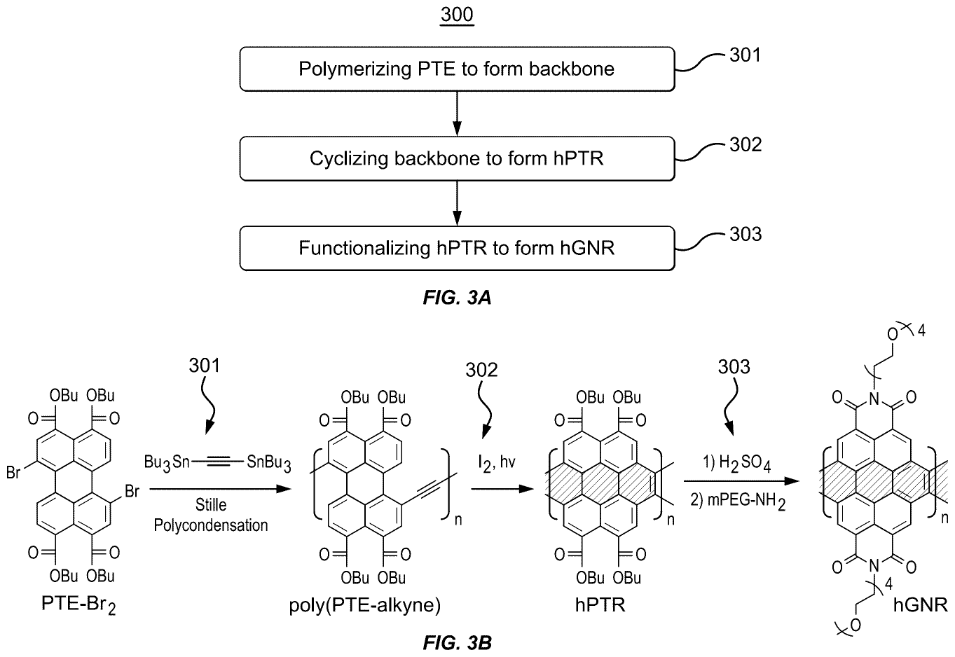

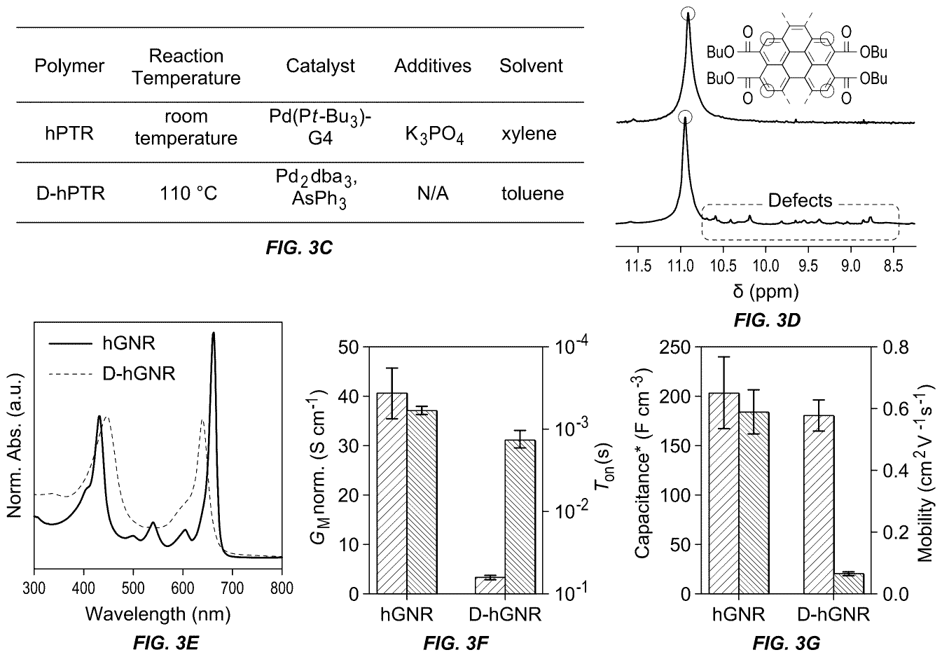

Referring to FIG. 3A, an exemplary method 300 for synthesizing an hGNR is illustrated according to certain embodiments of the disclosed subject matter. The method 300 includes a process protocol comprising sequential stages of polymerization, cyclization, and post-functionalization, where this sequence provides a scalable bottom-up synthetic route for producing defect-free helical graphene nanoribbons functionalized with polar substituents, thereby enabling controlled structural precision and tunable interfacial properties.

FIG. 3B depicts a corresponding microstructural modification during various reaction stages, aligned with the basic protocol in FIG. 3A. At 301, a perylene tetraester (PTE) monomer is polymerized to form a conjugated polymer backbone. In certain embodiments, a dibromo perylene tetraester (PTE-Br₂) can be employed to react with a bis(tributylstannyl)acetylene comonomer under Stille polycondensation conditions. Such polymerization can be processed at or near room temperature to suppress homo-coupling side reactions, thereby facilitating the generation of an alternating poly(PTE-alkyne) copolymer having a substantially defect-free backbone.

At 302, the conjugated polymer backbone undergoes a cyclization to form a helical perylene tetraester nanoribbon precursor (hPTR). In certain embodiments, the poly(PTE-alkyne) is subjected to visible-light-mediated photocyclization in a flow reactor, for example, under iodine catalysis and irradiation with visible light. The photocyclization can fuse adjacent aromatic units, thereby extending π-conjugation and inducing a contorted, helical conformation along the backbone. The resulting hPTR intermediate exhibits an extended fused aromatic structure suitable for subsequent chemical modification.

At 303, following the cyclization 302, the hPTR is post-functionalized to yield the hGNR product. In certain embodiments, the hPTR can be reacted with sulfuric acid to convert ester groups to imides, followed by condensation with an oligoethylene glycol amine (mPEG-NH₂). The post-functionalization introduces imide substituents along the cove edges of the nanoribbon, each bearing oligoethylene glycol side chains. The imide groups can lower the conduction band energy, facilitating efficient electron doping, while the oligoethylene glycol moieties enhance ionic conduction and solubility. The resulting hGNR product combines a defect-free graphitic backbone with polar edge substituents, enabling mixed ionic/electronic conduction properties.

The synthetic method suppresses defect formation and ensures uninterrupted π-conjugation throughout the backbone, important to achieving the high mobility and electrochemical performance in OECTs, described below.

Referring to FIG. 3C, an atomically precise poly(PTE-alkyne) alternating copolymer can be synthesized under the room-temperature coupling condition. A fully fused, defect-free backbone is indicated by ¹H NMR spectroscopy: a broad resonance peak in the aromatic region, which can be assigned to ortho-protons on perylenes, as shown in FIG. 3D. The post-functionalization of the hPTR forms to the hGNR decorated by imides with ethylene glycol groups. In the UV-Vis spectrum, the defect-free hGNR exhibits a sharp maximum absorption peak revealing a uniform backbone structure, as shown in FIG. 3E.

For comparison, defective hPTR (D-hPTR) is also synthesized through a typical thermally activated Stille polycondensation, which generates additional aromatic peaks in the ¹H NMR spectrum suggesting undesirable structural defects. The corresponding defective hGNR (D-hGNR) shows broader and less-defined peaks with a 15 nm blueshift in the absorption spectrum, as shown in FIG. 3E. Notably, there is a single broad resonance in the ¹H NMR spectrum consistent with desirable perylene products, without any unexpected peaks indicative of side products, without any unexpected peaks indicative of side products. These differences between the hGNR and D-hGNR can be attributed to the suppression of non-selective homocoupling reactions at lower temperatures during the Stille coupling process under the conditions described above, thereby preventing the generation of defect-inducing fragments after photocyclization and ensuring uninterrupted π-conjugation throughout the nanoribbon framework.

Referring to FIG. 3F, the OECT incorporating D-hGNR exhibits over an order of magnitude lower normalized transconductance of 3.30±0.43 S·cm⁻¹ and τₒₙ and τ_{off} times are also higher at 1.36±0.32 ms and 0.312±0.167 ms, respectively, compared to the hGNR-based OECT. Further referring to FIG. 3G, the difference of OECTs performance between the hGNR and D-hGNR on the μC* figure of merit is presented as mobility (μ) and volumetric capacitance (μC*), respectively. Using electrochemical impedance spectroscopy, capacitance values are extracted by fitting to a model, e.g., a Randles circuit model: Rs+R_{CT}/CPE, where Rs is the electrolyte resistance, R_{CT} is the charge-transfer resistance, and CPE is a constant phase element. Notably, both iterations of the hGNR and D-hGNR exhibit comparable volumetric capacitances of 203±36 F·cm⁻³ (hGNR) and 180±16 F·cm⁻³ (D-hGNR) (FIG. 3F), indicating that defects have minimal influence on charge-storage characteristics thereof. Calculated from the transfer curves and the aforementioned volumetric capacitances, hGNR and D-hGNR are found to possess p values of 0.589±0.071 cm² V⁻¹s⁻¹ and 0.0648±0.0062 cm² V⁻¹s⁻¹, respectively (FIG. 3G). Through the above comparison on electronical properties, the hGNR-based OECTs demonstrate larger transconductance and faster response times.

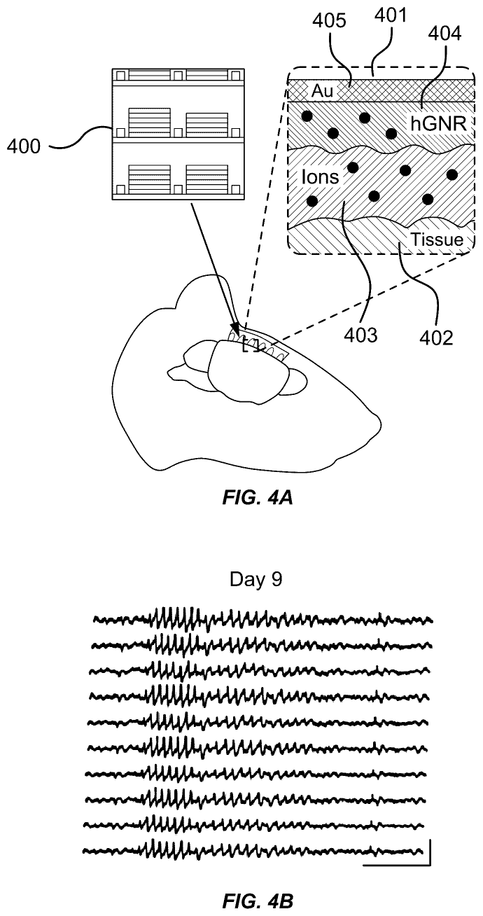

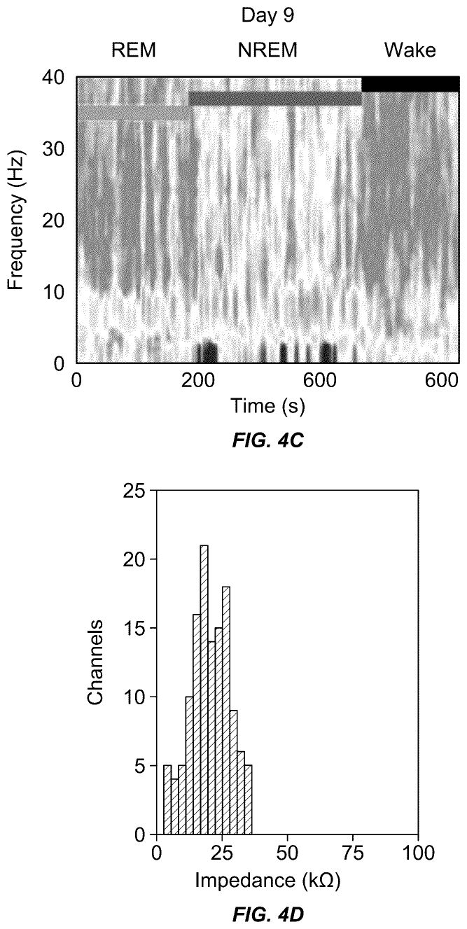

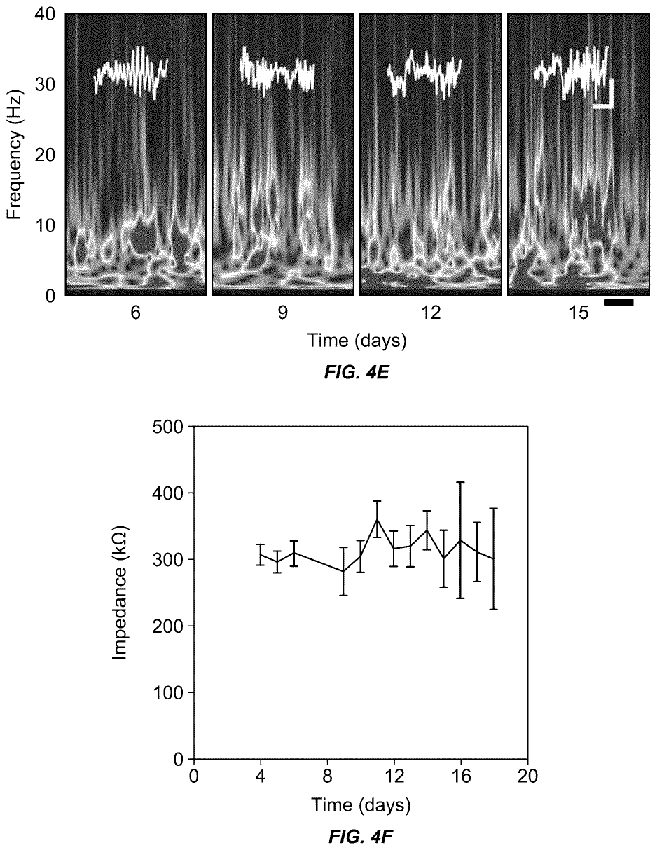

In certain embodiments, a conformable electrode array for recording electrical signals from neural tissue of a subject is assembled, and electrocorticography properties are investigated, as illustrated in FIGS. 4A-4F. FIG. 4A depicts a schematic diagram of a representative neural probe including hGNR-coated electrodes placed on the cortical surface of a tissue, e.g., the brain of a subject. A conformable electrode array 400 can comprise a flexible polymeric substrate 401, a plurality of patterned electrodes 403 disposed on the substrate, and a conductive coating 403 positioned on at least one of the electrodes, as shown in the left diagram of FIG. 4A. In certain embodiments, the electrodes 403 can have a gold (Au) layer 405 overlaid, e.g., as an electrode base, with the conductive coating 404. In operation, ions from the surrounding neural tissue 402 interact with the conductive coating 404, enabling stable mixed ionic/electronic conduction at the tissue-electrode interface.

The conductive coating 403 includes the hGNR having a defect-free extended backbone and oligoethylene glycol-functionalized imide groups along the cove edges of the nanoribbon. Accordingly, the conductive coating 403 provides mixed ionic/electronic conduction and biocompatibility, enabling the array to interface directly with cortical tissue and record electrophysiological signals. Such a configuration of the conformable electrode array can conform to the surface of a brain tissue, allowing stable interfacing with the neural tissue 402.

In certain embodiments, the electrodes of the conformable array can be configured as approximately 1-1000 μm², 1-800 μm², 1-500 μm², 1-300 μm², 1-200 μm², 1-100 μm², 30-80 μm², 40-50 μm², or approximately 40×40 μm² in size with an interelectrode spacing of approximately 10-1000 μm, 100-800 μm, 200-700 μm, 300-600 μm, 400-500 μm, or about 500 μm. The hGNR-coated electrodes exhibit low and consistent channel impedance both in benchtop measurements and in vivo, enabling high-quality neural interfacing and recordings, as shown in FIG. 4D. FIG. 4B illustrates representative data showing cortical oscillations consistent with delta spindle activity recorded on Day 9 of chronic local field potential (LFP) monitoring. FIG. 4C presents a time-frequency spectrogram from the same recording session, where signal content is classified into certain sleep states of the subject, including rapid eye movement (REM), non-REM, and waking states.

In additional embodiments, the conformable electrode array can be used for chronic recordings from a freely moving subject, where sessions of approximately two hours are conducted each day. As illustrated in FIG. 4E, spindle activity and non-REM sleep states are reproducibly detected across multiple days of recording. Impedance measurements in vivo, shown in FIG. 4F, demonstrate stable electrode performance across functional channels for more than two weeks. The combination of high temporal response, cation sensitivity, and biocompatibility of the hGNR coating enables long-term, stable recordings of cortical activity.

The above-discussed performance of the hGNR-coated electrodes demonstrates that the hGNR-based n-type conformable electrode array exhibits advantageous long-term stability in vivo, comparable to that of poly(3,4-ethylenedioxythiophene): polystyrene sulfonate (PEDOT:PSS), a benchmark p-type material. The stability, mixed ionic/electronic conduction, and compatibility with flexible substrates establish the hGNR as a promising candidate for translational bioelectronics applications including brain-machine interfaces, electrocorticography, and implantable neural probes.

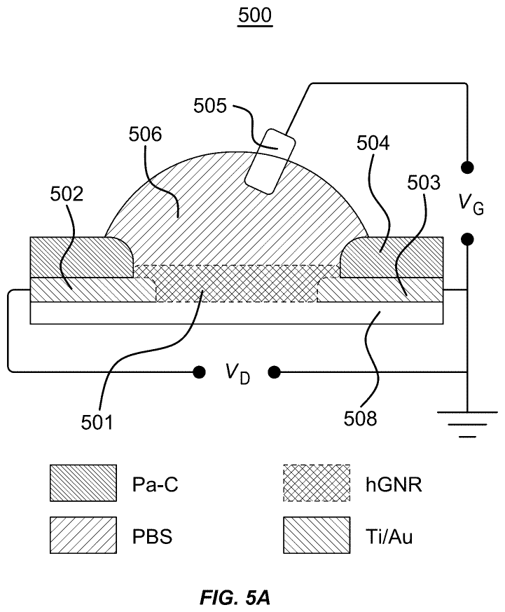

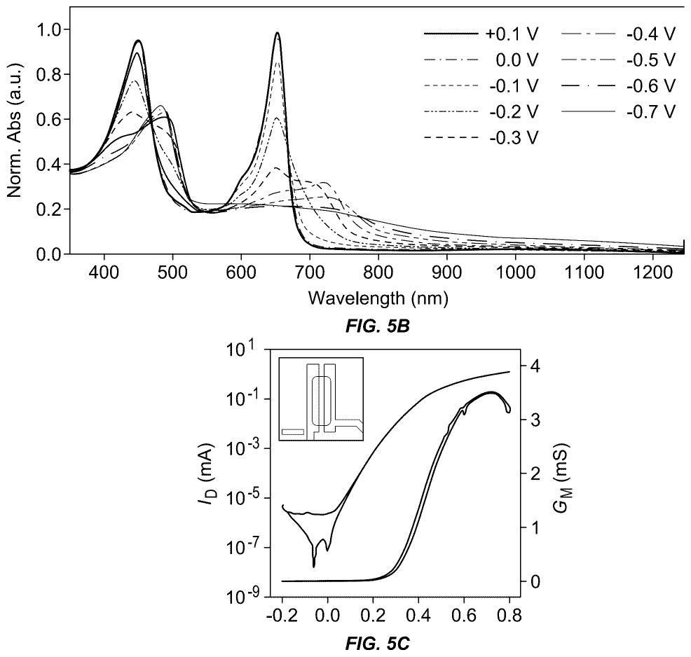

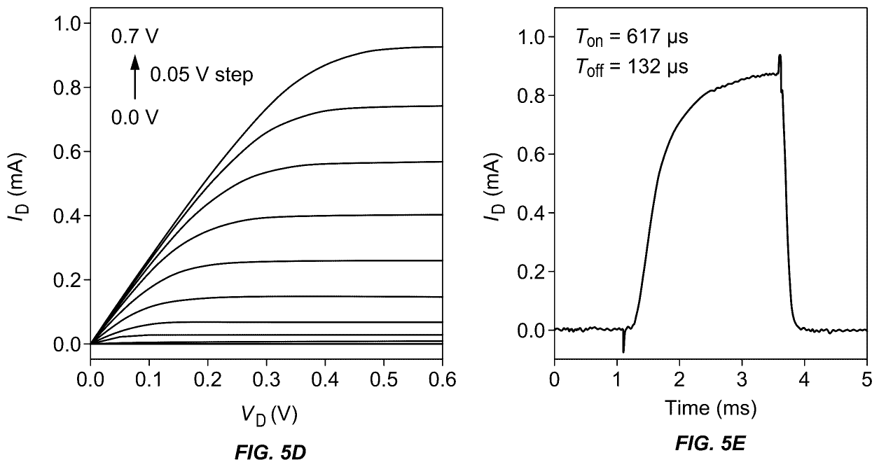

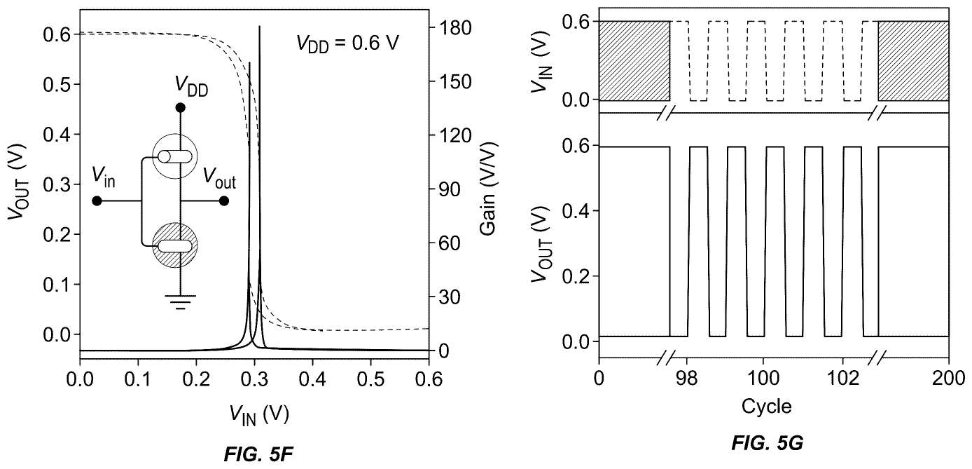

In certain embodiments, an exemplary organic electrochemical transistor (OECT) 500 can be illustrated as shown in FIG. 5A. The OECT 500 includes a channel layer 501 comprising an hGNR material. The channel layer 501 includes a defect-free extended graphitic backbone and a plurality of oligoethylene glycol-functionalized imide groups disposed along cove edges of the nanoribbon, thereby providing mixed ionic and electronic conduction. A source electrode 502 and a drain electrode 503 are disposed in electrical communication with the channel layer 501. In such embodiments, the source/drain electrodes 502, 503 can comprise a titanium/gold (Ti/Au) bilayer. An insulating layer 507 is positioned over the source electrode 502 and drain electrode 503 to electrically isolate the electrodes, thereby defining an exposed channel region for ionic coupling through the electrolyte 506. In certain embodiments, the insulating layer 507 comprises parylene C (Pa-C).

The OECT 500 further includes a gate electrode 505 configured to modulate ionic and electronic transport within the channel layer 501 through an electrolyte 506. In certain embodiments, the gate electrode 505 comprises a silver/silver chloride (Ag/AgCl) electrode immersed in an aqueous electrolyte, e.g., the electrolyte 506. The electrolyte 506, such as phosphate-buffered saline (PBS), is positioned over the channel layer 501 and electrically couples the channel to the gate electrode 505. The electrolyte 506 facilitates ingress and egress of ions during gating, thereby enabling electrochemical doping and de-doping of the channel layer 501. In addition, a substrate 508 is provided to have the channel layer 501 patterned thereon and to support the source/drain electrodes 502 and 503 and the insulating layer 504, thereby providing mechanical stability and structural integrity to the OECT 500. The substrate 508 can comprise a flexible polymeric material or a rigid insulating material, thereby providing structural stability for the OECT 500.

In operation, application of a gate voltage V_{G} to the gate electrode 505 drives ionic motion within the electrolyte 506, which sequentially modulates the electronic conductivity of the channel layer 501. Current flows between the source electrode 502 and drain electrode 503 under an applied drain voltage V_{D}, with the magnitude of the current being controlled by the gate voltage V_{G}.

Referring to FIG. 5B, the spectroelectrochemical measurements are presented to evaluate the optical properties of the hGNR-based OECT upon an electrochemical reduction at a bias of +0.1 V vs. Ag/AgCl. The hGNR-based OECT demonstrates two distinct absorption peaks approximately at 447 nm and 650 nm from the neutral perylene diimide (PDI) core. A reduction from +0.1 V to −0.7 V leads to the two distinct absorption peaks progressively diminishing in intensity and becoming predominantly absent at −0.7 V. Additionally, a considerable broad transition ranging from 650 nm to >1250 nm emerges, signaling the generation of a new polaronic species. Furthermore, the broad profile of the polaronic absorption band indicates extensive charge delocalization along the nanoribbon backbone, which is consistent with high electron mobility and supports the improved OECT performance.

The mixed conduction properties of hGNR are evaluated through the hGNR incorporation into OECTs as the active channel thin layer (shown in FIG. 5B). Referring to FIGS. 5C-5D, the GNR exhibits improved n-type accumulation mode transfer (FIG. 5C) and output (FIG. 5D) characteristics, featuring a low threshold voltage of 0.26 V, substantial I_{on/off} ratios (>10⁶), and an exceptionally high normalized transconductance (G_{m, norm}) of 40.6±5.1 S·cm⁻¹. Additionally, the hGNR-based OECT displays remarkably swift τₒₙ and τ_{off} values of 593±68 μs and 73±39 μs, respectively, under application of a 0.7 V gate pulse (as illustrated in FIG. 5E). In certain embodiments, to assess the compatibility of the hGNR in an integrated circuitry (IC), a complementary inverter using hGNR and p(g2T-TT) with a switching frequency of 8 Hz is fabricated to demonstrate substantial gains as high as 180 at V_{IN}=0.3 V (FIG. 5F) with fast response and adequate cycling stability at over 200 cycles (FIG. 5G). These experimental results effectively demonstrate the importance of functionalized hGNR as mixed conductors in n-type devices.

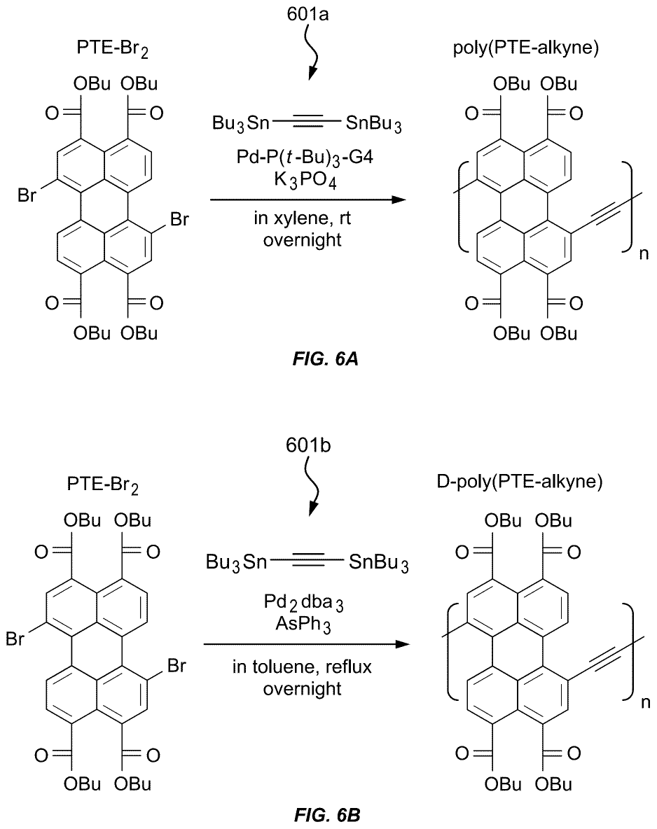

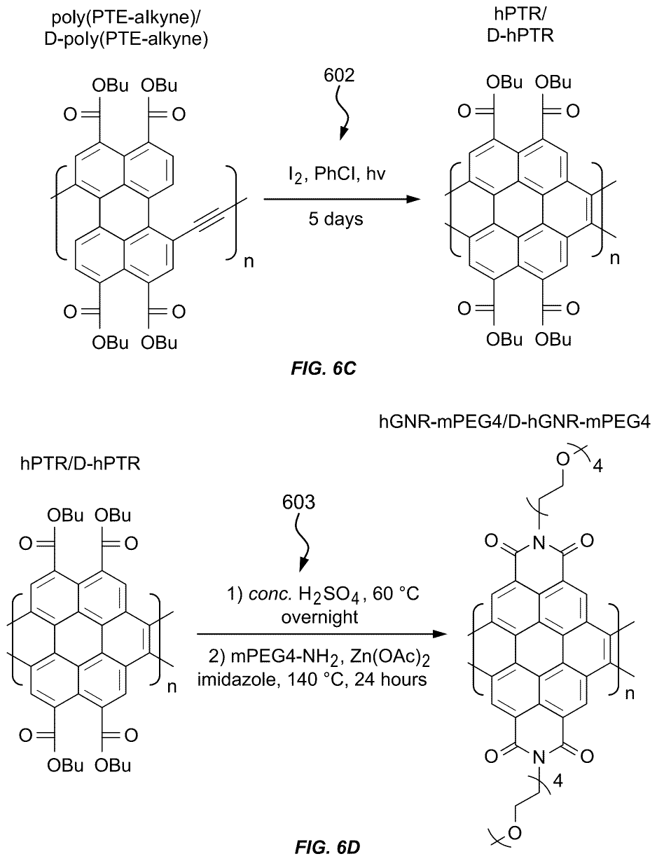

The examples discussed below illustrate exemplary synthetic procedures and representative structures of helical graphene nanoribbons (hGNRs) and defect-containing helical graphene nanoribbons (D-hGNRs) prepared under certain exemplary reaction conditions. Referring to FIG. 6A, a polymerization 601 can be operated via a perylene tetraester (PTE) monomer to form a conjugated polymer backbone, corresponding to 301 as shown in FIG. 3B. In certain examples, under N₂ protection, PTE-Br₂ (1.0 g, 1.23 mmol, 1.00 equiv., mixture of regioisomers) and bis(tri-n-butylstannyl) acetylene (745 mg, 1.23 mmol, 1.00 equiv.) are dissolved in anhydrous xylene (50 mL). Pd—P(t-Bu)₃-G4 (18 mg, 31 mol, 0.025 equiv.) and K₃PO₄ (157 mg, 1.23 mmol, 1.00 equiv.) are added to the solution and the reaction mixture is stirred at room temperature overnight under N₂ protection. The solution is poured into methanol (1 L) and the precipitates are purified by Soxhlet extraction (methanol for 4 hours, acetone for 16 hours, hexane for 4 hours and chloroform for 4 hours). The chloroform-extracted fraction is collected and dried under vacuum, yielding poly(PTE-alkyne) without substantial defects as a dark purple solid (730 mg, 87.5%).

Alternatively, referring to FIG. 6B, D-poly(PTE-alkyne) can be synthesized within alternative conditions via 601b. For example, under N₂ protection, PTE-Br₂ (1.0 g, 1.23 mmol, 1.00 equiv., mixture of regioisomers), Pd₂(dba)₃ (57 mg, 62 mol, 0.05 equiv.) and AsPh₃ (76 mg, 0.25 mmol, 0.20 equiv.) are dissolved in anhydrous toluene (50 mL). Bis(tri-n-butylstannyl) acetylene (745 mg, 1.23 mmol, 1.00 equiv.) are added to the solution and the reaction mixture is refluxed for 48 hours under N₂ protection. The solution is then cooled to room temperature and poured into methanol (1 L). The precipitates are purified by Soxhlet extraction (methanol for 4 hours, acetone for 16 hours, hexane for 4 hours and chloroform for 4 hours). The chloroform-extracted fraction is collected and dried under vacuum yielding D-poly(PTE-alkyne) as a dark purple solid (652 mg, 78.2%).

Following 601a/601b, helical perylene tetraester ribbons (hPTR/D-hPTR) are synthesized via 602, shown as in FIG. 6B. In certain experimental examples, in a 500-mL round bottom flask, poly(PTE-alkyne) or D-poly(PTE-alkyne) (700 mg) is dissolved in a solution of I₂ in chlorobenzene (300 mL, 1.5 mg mL⁻¹) and photocyclized with white light for 5 days. The reaction mixture is dried under vacuum, redissolved in the minimum volume of chloroform and precipitated using hexane. The precipitates are purified by Soxhlet extraction (acetone for 16 hours and chloroform for 4 hours). The chloroform-extracted fraction is collected and dried under vacuum yielding the cyclized polymer as a red solid (632 mg, 92% for hPTR; 425 mg, 60% for D-hPTR).

Following 602, certain contorted acene ribbons (hGNR-mPEG4/D-hGNR-mPEG4) are synthesized via 603, shown as in FIG. 6C. In certain examples, in a 20-mL vial, hPTR or D-hPTR (165 mg) is mixed with 10 mL concentrated sulfuric acid. The dark green suspension is vigorously stirred and heated at 60° C. overnight. The reaction mixture is poured in water/ice mixture (200 mL). The precipitates are collected by filtration through PTFE filter membrane (pore size: 1.5 μm), and then washed with water, methanol and acetone. The resulting dark green solid is dried under vacuum yielding the polymer anhydride (100 mg, 98.5%) and used without further purification. Under N₂ protection, the polymer anhydride (100 mg), mPEG4-amine (299 mg, 1.44 mmol), Zn(OAc)₂ (0.5 mg, catalytic amount) and imidazole (5.0 g) are added to a 20-mL vial and heated at 140° C. for 24 hours. The reaction mixture is cooled to 100° C. and poured into 2M HCl aqueous solution (200 mL). The mixture is sonicated and filtered to collect the precipitates. The crude product is washed with 2M HCl aqueous solution, methanol and acetone, and then dried under vacuum at 120° C. overnight, yielding hGNR-mPEG4 or D-hGNR-mPEG4 as a dark green solid (190 mg, quantitative yield).

By modifying synthesis conditions, such as reaction temperature, catalyst composition, reaction time, and other related parameters, alternative structural variants of contorted acene nanoribbons can be generated in a controllable manner. Such variations allow precise tuning of nanoribbon curvature, π-conjugation length, and electronic characteristics, thereby providing for improvement or optimization of material performance for targeted device applications.

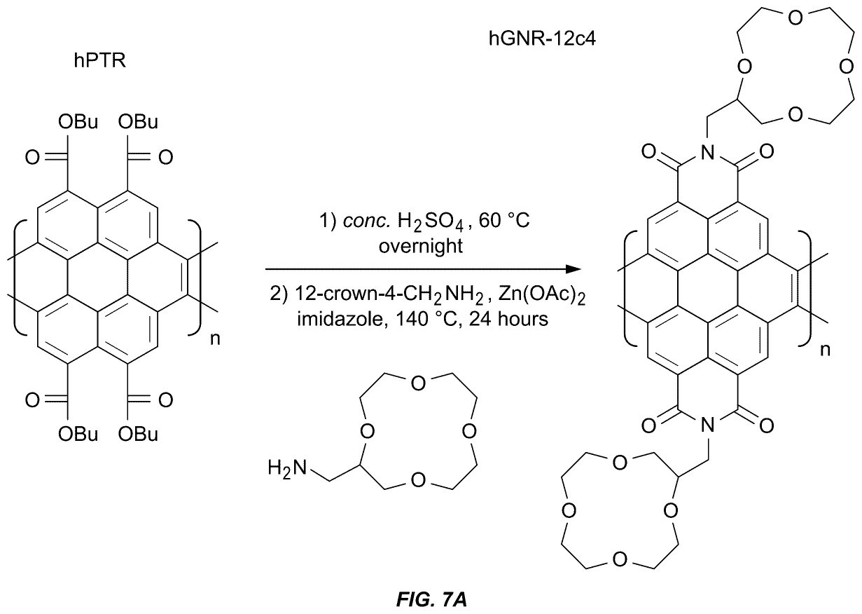

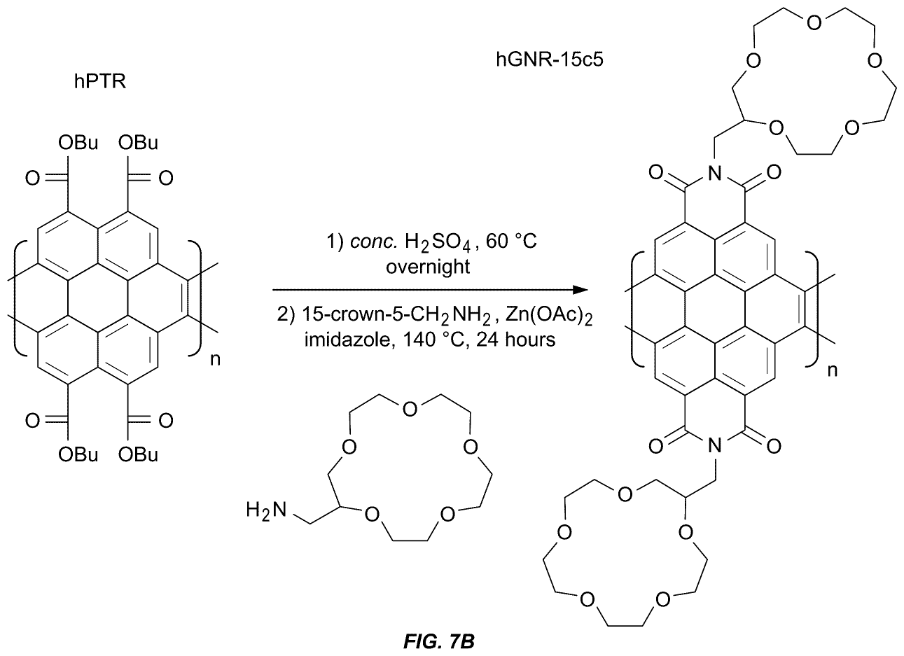

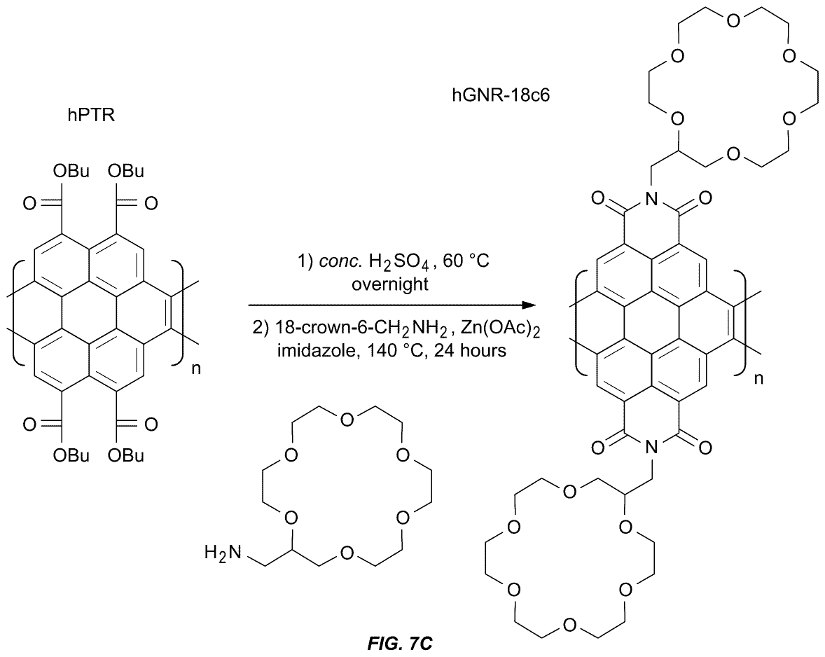

In certain examples, a helical graphene nanoribbon functionalized with 12-crown-4 ether side chains (hGNR-12c4) can be synthesized, as shown in FIG. 7A. In a 20-mL vial, hPTR (165 mg) is mixed with 10 mL concentrated sulfuric acid. The dark green suspension is vigorously stirred and heated at 60° C. overnight. The reaction mixture is poured in water/ice mixture (200 mL). The precipitates are collected by filtration through PTFE filter membrane (pore size: 1.5 μm), and then washed with water, methanol and acetone. The resulting dark green solid is dried under vacuum yielding the polymer anhydride (100 mg, 98.5%) and used without further purification. Under N₂ protection, the polymer anhydride (100 mg), 12-crown-4-CH₂NH₂ (296 mg, 1.44 mmol), Zn(OAc)₂ (0.5 mg, catalytic amount) and imidazole (5.0 g) are added to a 20-mL vial and heated at 140° C. for 24 hours. The reaction mixture is cooled to 100° C. and poured into 2M HCl aqueous solution (200 mL). The mixture is sonicated and filtered to collect the precipitates. The crude product is washed with 2M HCl aqueous solution, methanol and acetone, and then dried under vacuum at 120° C. overnight, yielding hGNR-12c4 as a dark green solid (190 mg, quantitative yield).

In certain examples, a helical graphene nanoribbon functionalized with 12-crown-4 ether side chains (hGNR-15c5) can be synthesized, as shown in FIG. 7B. In a 20-mL vial, hPTR (165 mg) is mixed with 10 mL concentrated sulfuric acid. The dark green suspension is vigorously stirred and heated at 60° C. overnight. The reaction mixture is poured in water/ice mixture (200 mL). The precipitates are collected by filtration through PTFE filter membrane (pore size: 1.5 μm), and then washed with water, methanol and acetone. The resulting dark green solid is dried under vacuum yielding the polymer anhydride (100 mg, 98.5%), and used f without further purification. Under N₂ protection, the polymer anhydride (100 mg), 15-crown-5-CH₂NH₂ (359 mg, 1.44 mmol), Zn(OAc)₂ (0.5 mg, catalytic amount) and imidazole (5.0 g) are added to a 20-mL vial and heated at 140° C. for 24 hours. The reaction mixture is cooled to 100° C. and poured into 2M HCl aqueous solution (200 mL). The mixture is sonicated and filtered to collect the precipitates. The crude product is washed with 2M HCl aqueous solution, methanol and acetone, and then dried under vacuum at 120° C. overnight, yielding hGNR-15c5 as a dark green solid (211 mg, quantitative yield).

In certain examples, a helical graphene nanoribbon functionalized with 12-crown-4 ether side chains (hGNR-18c6) can be synthesized, as shown in FIG. 7C. In a 20-mL vial, hPTR (165 mg) is mixed with 10 mL concentrated sulfuric acid. The dark green suspension is vigorously stirred and heated at 60° C. overnight. The reaction mixture is poured in a water/ice mixture (200 mL). The precipitates are collected by filtration through PTFE filter membrane (pore size: 1.5 μm), and then washed with water, methanol and acetone. The resulting dark green solid is dried under vacuum yielding the polymer anhydride (100 mg, 98.5%), and used without further purification. Under N₂ protection, the polymer anhydride (100 mg), 18-crown-6-CH₂NH₂ (422 mg, 1.44 mmol), Zn(OAc)₂ (0.5 mg, catalytic amount) and imidazole (5.0 g) are added to a 20-mL vial and heated at 140° C. for 24 hours. The reaction mixture is cooled to 100° C. and poured into 2M HCl aqueous solution (200 mL). The mixture is sonicated and filtered to collect the precipitates. The crude product is washed with 2M HCl aqueous solution, methanol and acetone, and then dried under vacuum at 120° C. overnight, yielding hGNR-18c6 as a dark green solid (232 mg, quantitative yield).

In certain embodiments, the disclosed subject matter provides usages of the above helical graphene nanoribbon (hGNR) materials functionalized with crown ether moieties in organic electrochemical transistors (OECTs). Functional side chains can enhance modulating ionic interactions and electrochemical behavior in such devices. Crown ether-functionalized hGNRs can be advantageous due to their capability to enable selective ion transport and to influence the overall transistor performance. In such embodiments, crown ether groups such as 12-crown-4 (12c4) and 15-crown-5 (15c5) are incorporated along the cove edges of a fully fused, ladder-type hGNR backbone. These functional groups facilitate fine-tuning of ion selectivity, volumetric capacitance, and charge-carrier mobility. The performance of the resulting crown-ether-functionalized hGNRs in OECTs can be evaluated in terms of transconductance, threshold voltage response to specific ionic species, and spectroelectrochemical characteristics, thereby demonstrating the structural-functional relationship between crown ether size and the mixed ionic/electronic transport properties of the hGNR framework.

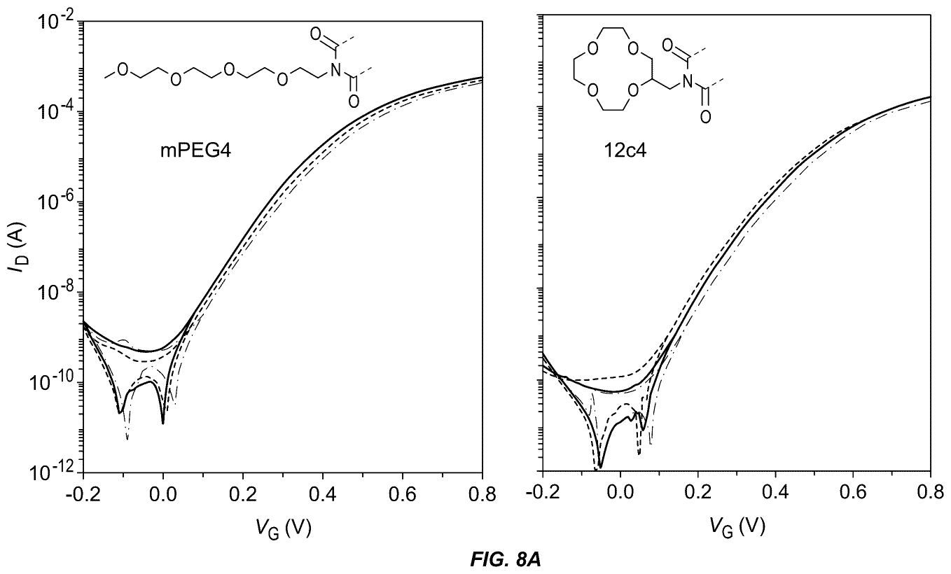

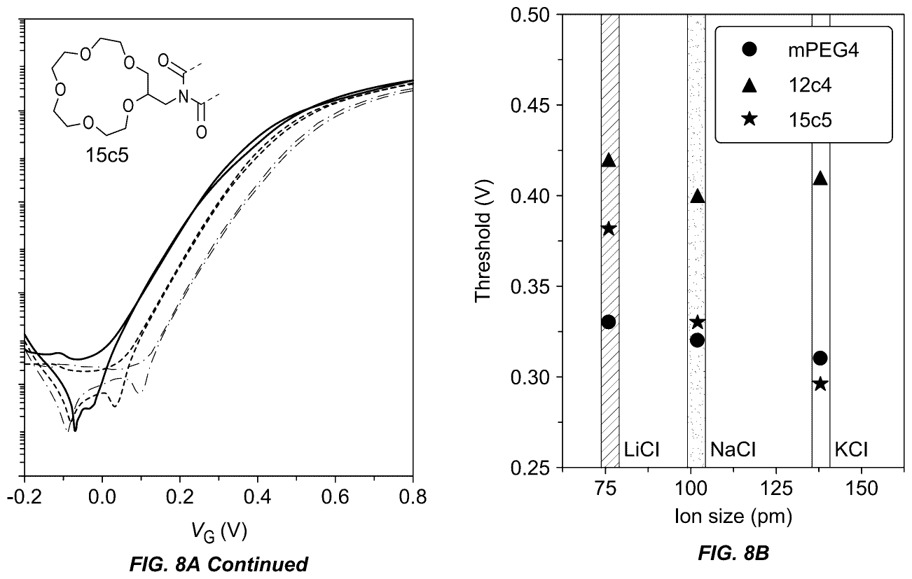

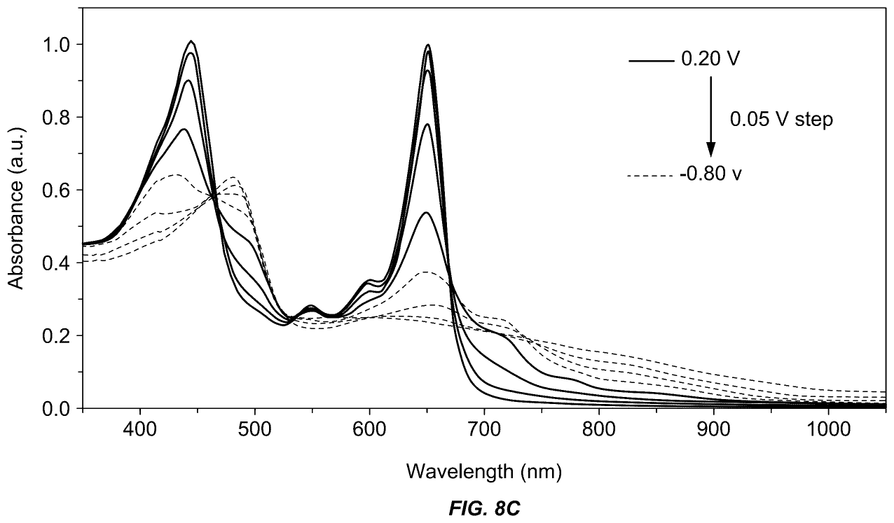

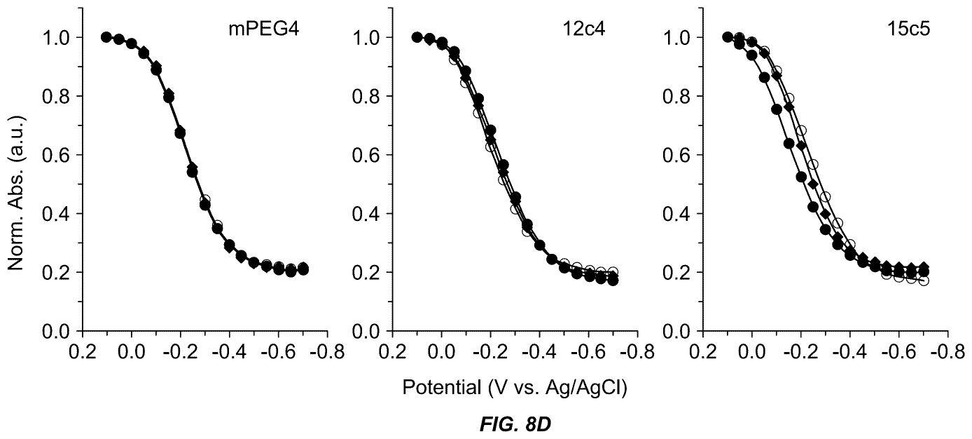

In certain embodiments, crown-ether-functionalized hGNR exhibit OECT performance comparable to the mPEG4-functionalized counterparts, with a transconductance (Gₘ) of ˜1-10 S·cm⁻¹, indicating that crown substitution does not significantly disrupt electron transport pathways (FIG. 8A). As demonstrated, hGNR-mPEG4 show minimal selectivity toward Li⁺, Na⁺, or K⁺, with threshold voltages (Vth) of 0.33 V, 0.325 V, and 0.31 V, respectively (FIG. 8B). In contrast, OECTs based on hGNR-12c4 display elevated threshold voltages of 0.42 V, 0.40 V, and 0.41 V in the presence of LiCl, NaCl, and KCl, suggesting reduced ion insertion due to the rigidity of the cyclic ether. Incorporation of a 15c5 side chain results in pronounced ion-specific modulation, with Vth values of 0.30 V (K⁺), 0.32 V (Na⁺), and 0.38 V (Li⁺), highlighting a clear selectivity trend favoring K⁺ insertion over Na⁺ and Li⁺. Additionally, the lack of hysteresis in all OECTs demonstrates that these ion-sidechain interactions are highly reversible.

A similar trend is presented in the spectroelectrochemical response of the polymers. Upon stepwise electrochemical reduction as thin films on ITO, all devices exhibit a consistent spectral evolution marked by a decrease in absorption at 650 nm and 450 nm and the emergence of a broad polaronic band beyond 1100 nm (FIG. 8C). Both hGNR-mPEG4 and -12c4 display nearly identical absorption profiles as a function of reduction potential (FIG. 8D). In contrast, hGNR-15c5 demonstrates an earlier onset of reduction in the presence of KCl, indicating enhanced ionic interactions. Notably, at more negative potentials, the extent of absorption change diminishes. These illustrations shown in FIGS. 8A-8D demonstrate that ion insertion dynamics which are the primary driving force at smaller voltages, are most significantly influenced by the presence and structure of cyclic side chains.

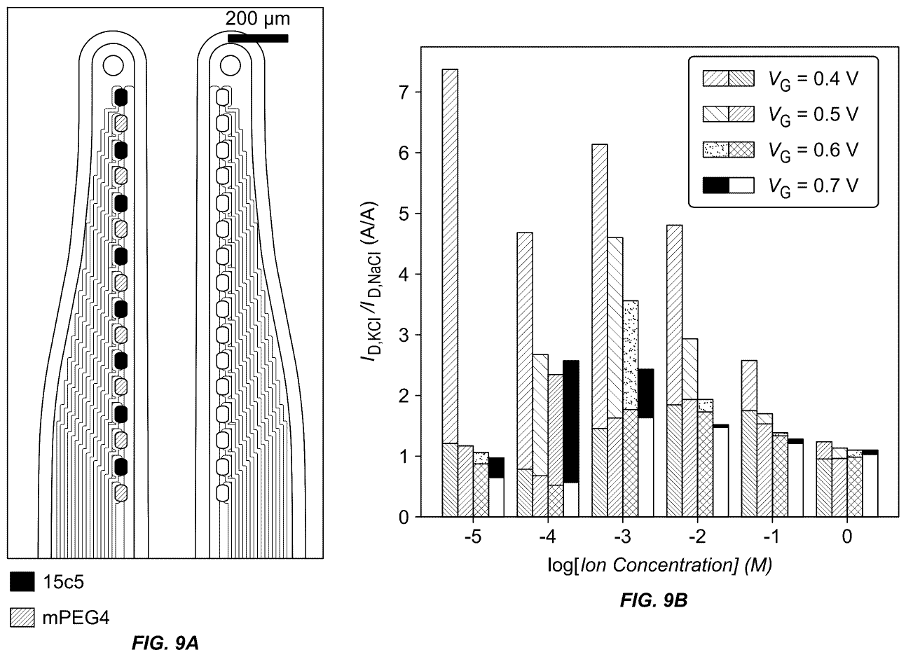

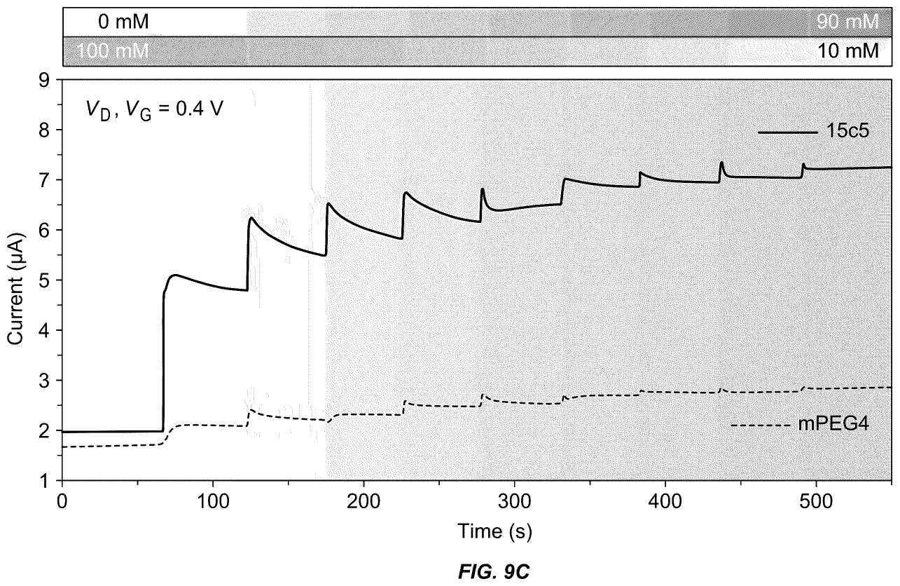

In certain embodiments, given the comparable performance of methoxy polyethylene glycol (mPEG4)- and 15-crown-5 (15c5)-functionalized hGNRs in organic electrochemical transistors (OECTs), the disclosed subject matter provides certain sensor architectures that integrate both transistor types to enhance ion sensitivity In the configuration shown in FIG. 9A, hGNR-mPEG4 functions as the control device, while hGNR-15c5 acts as the sensing element. When evaluating the selectivity of both devices toward NaCl and KCl, it has been observed that at a gate voltage (V_{G}) of 0.4 V, hGNR-15c5 produces a current six times higher in the presence of KCl compared to NaCl, whereas hGNR-mPEG4 shows less than twice the current intensity (FIG. 9B). This selective response is further corroborated by real-time current measurements, where increasing KCl concentration leads to a significant current increase in hGNR-15c5 devices, with minimal impact on hGNR-mPEG4 devices (FIG. 9C). These results demonstrate leveraging crown-ether-functionalized hGNRs to achieve ion-specific detection and pave the way for advanced electrochemical and bioelectronic sensors capable of selective ion recognition across diverse analyte environments.

The foregoing merely illustrates the principles of the disclosed subject matter. Various modifications and alterations to the described embodiments will be apparent to those skilled in the art in view of the teachings herein. Further, it should be noted that the language used herein has been selected for readability rather than to delineate or limit the disclosed subject matter. Accordingly, the disclosure herein is intended to be illustrative, but not limiting, of the scope of the disclosed subject matter. Moreover, the principles of the disclosed subject matter can be implemented in various configurations and are not intended to be limited in any way to the specific embodiments presented herein. It will thus be appreciated that those skilled in the art will be able to devise numerous systems, arrangements, and procedures which, although not explicitly shown or described herein, embody the principles of the disclosure and can be thus within the spirit and scope of the disclosure.

What is claimed is:

1. A method of synthesizing a helical graphene nanoribbon (hGNR), comprising:
polymerizing a perylene tetraester with an alkyne monomer to form a polymer backbone;
inducing the polymer backbone to visible-light-mediated photocyclization, to generate a helical nanoribbon precursor; and
post-functionalizing the helical nanoribbon precursor with imide groups having oligoethylene glycol substituents along cove edges of the nanoribbon,
thereby forming a substantially defect-free hGNR.

2. The method of claim 1, wherein the polymerizing is performed by Stille coupling reaction under room-temperature conditions.

3. The method of claim 2, wherein the Stille coupling reaction is catalyzed by a palladium-based catalyst.

4. The method of claim 2, wherein the Stille coupling reaction is conducted in an organic solvent selected at least one from the group consisting of toluene, dimethylformamide (DMF), and N-methylpyrrolidone (NMP).

5. The method of claim 1, wherein the polymerizing is configured to suppress homo-coupling side reactions.

6. The method of claim 1, wherein the visible-light-mediated photocyclization is performed in a flow reactor.

7. The method of claim 1, further comprising depositing the defect-free hGNR as a thin film on a substrate to form a channel layer of an organic electrochemical transistor.

8. The method of claim 1, wherein at least a portion of the imide groups having oligoethylene glycol substituents is functionalized with crown ether groups.

9. The method of claim 8, wherein the crown ether groups are selected at least one of 12-crown-4, 15-crown-5, and 18-crown-6.

10. The method of claim 1, wherein at least a portion of the imide groups having oligoethylene glycol substituents is functionalized with methoxy polyethylene glycol.

11. A conformable electrode array for recording electrical signals from neural tissue of a subject, comprising:
a substrate;
a plurality of electrodes patterned on the substrate; and
a conductive coating disposed on at least one of the electrodes, the conductive coating comprising a helical graphene nanoribbon (hGNR) having oligoethylene glycol-functionalized imide groups along cove edges of the nanoribbon,
wherein the conformable electrode array is configured to interface with the neural tissue to record the electrical signals therefrom.

12. The conformable electrode array of claim 11, wherein the electrodes are configured to have dimensions of about 1-1000 micrometers by about 1-1000 micrometers with an interelectrode spacing of about 10-1000 micrometers.

13. The conformable electrode array of claim 11, wherein the conformable electrode array is configured to record neuronal oscillations including delta spindles during sleep states of the subject.

14. An organic electrochemical transistor (OECT), the transistor comprising:
a channel layer comprising a helical graphene nanoribbon (hGNR) having a defect-free extended graphitic backbone and a plurality of oligoethylene glycol-functionalized imide groups along cove edges of the hGNR;
a substrate having the channel layer patterned thereon;
a source electrode and a drain electrode in electrical communication with the channel layer; and
a gate electrode configured to modulate ionic and electronic transport within the channel layer through an electrolyte.

15. The organic electrochemical transistor of claim 14, wherein the source electrode and the drain electrode comprise a titanium/gold bilayer.

16. The organic electrochemical transistor of claim 14, wherein the gate electrode comprises a silver/silver chloride (Ag/AgCl) electrode.

17. The organic electrochemical transistor of claim 14, wherein the electrolyte comprises an aqueous solution selected at least one of phosphate-buffered saline (PBS), and saline.

18. The organic electrochemical transistor of claim 14, further comprising an insulating layer disposed on the source electrode and the drain electrode.

19. The organic electrochemical transistor of claim 14, wherein the transistor is configured to integrate with a p-type organic conductor to fabricate a complementary inverter.
